(19) United States
(12) Patent Application Publication
(10) Pub. No.: US 2023/0066543 A1
(43) Pub. Date: Mar. 2, 2023

(54) FULLY SELF ALIGNED VIA INTEGRATION PROCESSES

(71) Applicant: Applied Materials, Inc., Santa Clara, CA (US)

(72) Inventor: Xintuo DAI, Rexford, NY (US)

(21) Appl. No.: 17/866,399

(22) Filed: Jul. 15, 2022

Related U.S. Application Data
(60) Provisional application No. 63/236,528, filed on Aug. 24, 2021.

(51) Int. Cl. H01L 23/522; H01L 21/768; H01L 21/3105; H01L 21/321

(52) U.S. Cl. CPC H01L 23/5226; H01L 21/76877; H01L 21/76819; H01L 21/31053; H01L 21/76802; H01L 21/76831; H01L 21/7684; H01L 21/3212

(57) ABSTRACT

A method of fabricating fully self-aligned vias includes performing a first deposition process, forming a second dielectric layer, performing a first chemical mechanical polishing (CMP) process, performing a selective removal plasma process to form second vias, performing a second deposition process to deposit an etch stop layer in the second vias, performing a third deposition process, forming a third dielectric layer, performing a second CMP process, performing a first lithography-and-etch process to form third vias in the third dielectric layer, performing a fourth deposition process to form a second metal layer in the third vias, performing a fourth CMP process, performing a fifth deposition process to form a third metal layer of third metal, performing a sixth deposition process to form a second hardmask, performing a second lithography-and-etch process, performing an over etch, performing a seventh deposition process, forming a fourth dielectric layer, performing a fifth CMP process.

### CROSS-REFERENCE TO RELATED APPLICATIONS

This application claims the benefit to U.S. Provisional Application No. 63/236,528, filed Aug. 24, 2021, which is incorporated by reference herein.

### BACKGROUND

### Field

Embodiments described herein generally relate to semiconductor device fabrication, and more particularly, to methods of forming fully self-aligned vias in the back end of line (BEOL).

### Description of the Related Art

In the manufacture of integrated circuits (IC), or chips, patterns representing different layers of the chip are created by a chip designer. Typically IC includes one or more metal layers having metal lines to connect electronic devices of the IC to one another and to external connections in the back end of line (BEOL), and dielectric interlayers are placed between metal layers. As the size of the IC decreases, spacing between the metal lines decreases. Thus, aligning such an interconnect structure in one metal layer with an interconnect structure in another metal layer has become a challenge by the conventional manufacturing techniques, in which patterning of one metal layer is performed independently from the vias above that metal layer, and thus an interconnect structure in an upper metal layer is often misaligned with an interconnect structure in a lower metal layer. Such misalignment of interconnect structures increases resistance and leads to potential shorting to a wrong metal line. This causes device failures, decreases yield, and increases manufacturing cost.

Therefore, there is a need for methods of forming vias, in which metal is filled to form an interconnect structure, in a fully self-aligned manner.

### SUMMARY

Embodiments of the present disclosure provide a method of fabricating fully self- aligned vias. The method includes performing a first deposition process to fill openings of a first hardmask and first vias formed within a first metal layer formed of first metal underneath the first hardmask and on a first dielectric layer formed of low-k dielectric material, with the low-k dielectric material, forming a second dielectric layer, performing a first chemical mechanical polishing (CMP) process to planarize the second dielectric layer and partially remove the first hardmask, performing a selective removal plasma process to selectively remove the remaining first hardmask and form second vias within the second dielectric layer, performing a second deposition process to deposit an etch stop layer in the second vias and on the second dielectric layer, performing a third deposition process to fill the second vias over the etch stop layer with the low-k dielectric material, forming a third dielectric layer, performing a second CMP process to planarize the third dielectric layer, performing a first lithography-and-etch process to form third vias in the third dielectric layer, the first lithography-and-etch process comprising a lithography process, an etch process, and a third CMP process, performing a fourth deposition process to fill the third vias with second metal to form a second metal layer in the third vias and on the third dielectric layer, performing a fourth CMP process to planarize the second metal layer and the third dielectric layer and remove portions of the second metal layer outside the third vias, performing a fifth deposition process to form a third metal layer of third metal on the second metal layer and the third dielectric layer, performing a sixth deposition process to form a second hardmask on the third metal layer, performing a second lithography-and-etch process to form fourth vias in the third metal layer, performing an over etch process to partially etch the second metal layer in the fourth vias, performing a seventh deposition process to fill the fourth vias with the low-k dielectric material, forming a fourth dielectric layer, performing a fifth CMP process to planarize the fourth dielectric layer and partially remove the second hardmask.

Embodiments of the present disclosure also provide a nanostructure formed on a substrate. The nanostructure includes a first dielectric layer formed on a substrate, a second dielectric layer disposed on the first dielectric layer, the second dielectric layer having a plurality of first interconnect structures formed therein, a third dielectric layer disposed on the second dielectric layer, the third dielectric layer having a plurality of second interconnect structures formed therein, wherein the plurality of second interconnect structures are self-aligned with the plurality of first interconnect structures, and a fourth dielectric layer disposed on the third dielectric layer, the fourth dielectric layer having a plurality of third interconnect structures formed therein, wherein the plurality of third interconnect structures are self-aligned with the plurality of second interconnect structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a processing chamber that may be utilized to perform a deposition process according to one embodiment.

FIG. 2 depicts a processing chamber that may be utilized to perform a patterning process according to one embodiment.

FIG. 3 is a flow diagram of a method 300 for fabricating fully self-aligned vias according to one embodiment.

FIGS. 4A, 4A′, 4B, 4B′, 4C, 4C′, 4D, 4D′, 4E, 4E′, 4F, 4F′, 4G, 4G′, 4H, 4H′, 4I, 4I′, 4J, 4J′, 4K, 4K′, 4L, 4L′, 4M, 4M′, 4N, 4N′, 4O, 4O′ are cross-sectional views of a portion of a film stack according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide methods for forming a fully self-aligned vias. Vias, which are filled with tungsten (W) or ruthenium (Ru) to form interconnect structures, in multiple metal layers are fully self-aligned, and thus device failure due to misalignment of interconnect structures is greatly reduced.

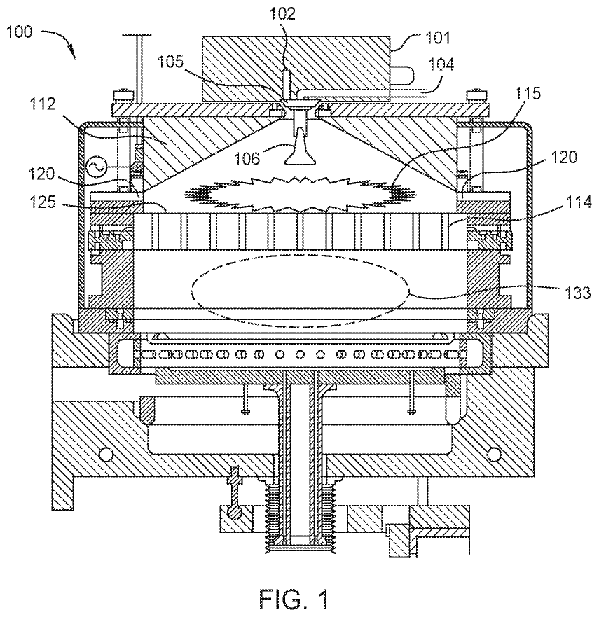

FIG. 1 is a cross-sectional view of one embodiment of a flowable chemical vapor deposition chamber 100 with partitioned plasma generation regions. The flowable chemical vapor deposition chamber 100 may be utilized to deposit a flowable silicon containing layer, such as a doped silicon containing layer, onto a substrate. Other flowable silicon containing layers may include silicon oxide, silicon carbide, silicon nitride, silicon oxynitride or silicon oxycarbide, among others. During film deposition, a process gas may be flowed into a first plasma region 115 through a gas inlet assembly 105. The process gas may be excited prior to entering the first plasma region 115 within a remote plasma system (RPS) 101. The deposition chamber 100 includes a lid 112 and showerhead 125. The lid 112 is depicted with an applied AC voltage source, and the showerhead 125 is grounded, consistent with plasma generation in the first plasma region 115. An insulating ring 120 is positioned between the lid 112 and the showerhead 125 enabling an inductively coupled plasma (ICP) or a capacitively coupled plasma (CCP) to be formed in the first plasma region 115. The lid 112 and showerhead 125 are shown with the insulating ring 120 in between, which allows an AC potential to be applied to the lid 112 relative to the showerhead 125.

The lid 112 may be a dual-source lid featuring two distinct gas supply channels within the gas inlet assembly 105. A first gas supply channel 102 carries a gas that passes through the remote plasma system (RPS) 101, while a second gas supply channel 104 bypasses the RPS 101. The first gas supply channel 102 may be used for the process gas, and the second gas supply channel 104 may be used for a treatment gas. The gases that flow into the first plasma region 115 may be dispersed by a baffle 106.

A fluid, such as a precursor, may be flowed into a second plasma region 133 of the deposition chamber 100 through the showerhead 125. Excited species derived from the precursor in the first plasma region 115 travel through apertures 114 in the showerhead 125 and react with the precursor flowing into the second plasma region 133 from the showerhead 125. Little or no plasma is present in the second plasma region 133. Excited derivatives of the precursor combine in the second plasma region 133 to form a flowable dielectric material on the substrate. As the dielectric material grows, more recently added material possesses a higher mobility than underlying material. Mobility decreases as organic content is reduced by evaporation. Gaps may be filled by the flowable dielectric material using this technique without leaving traditional densities of organic content within the dielectric material after deposition is completed. A curing step may still be used to further reduce or remove the organic content from the deposited film.

Exciting the precursor in the first plasma region 115 alone or in combination with the remote plasma system (RPS) 101 provides several benefits. The concentration of the excited species derived from the precursor may be increased within the second plasma region 133 due to the plasma in the first plasma region 115. This increase may result from the location of the plasma in the first plasma region 115. The second plasma region 133 is located closer to the first plasma region 115 than the remote plasma system (RPS) 101, leaving less time for the excited species to leave excited states through collisions with other gas molecules, walls of the chamber and surfaces of the showerhead.

The uniformity of the concentration of the excited species derived from the precursor may also be increased within the second plasma region 133. This may result from the shape of the first plasma region 115, which is more similar to the shape of the second plasma region 133. Excited species created in the remote plasma system (RPS) 101 travel greater distances in order to pass through apertures 114 near the edges of the showerhead 125 relative to species that pass through apertures 114 near the center of the showerhead 125. The greater distance results in a reduced excitation of the excited species and, for example, may result in a slower growth rate near the edge of a substrate. Exciting the precursor in the first plasma region 115 mitigates this variation.

In addition to the precursors, there may be other gases introduced at different times for various purposes. For example, a treatment gas may be introduced to remove unwanted species from the chamber walls, the substrate, the deposited film and/or the film during deposition. The treatment gas may comprise at least one or more of the gases selected from the group consisting of H₂, an H₂/N₂ mixture, NH₃, NH₄OH, O₃, O₂, H₂O₂ and water vapor. The treatment gas may be excited in a plasma, and then used to reduce or remove a residual organic content from the deposited film. In other examples, the treatment gas may be used without a plasma. When the treatment gas includes water vapor, the delivery may be achieved using a mass flow meter (MFM) and injection valve, or by utilizing other suitable water vapor generators.

In one embodiment, the doped silicon containing layer may be deposited by introducing silicon containing precursors and reacting processing precursors in the second plasma region 133. Examples of dielectric material precursors are silicon containing precursors including silane, disilane, methylsilane, dimethylsilane, trimethylsilane, tetramethylsilane, tetraethoxysilane (TEOS), triethoxysilane (TES), octamethylcyclotetrasiloxane (OMCTS), tetramethyl-disiloxane (TMDSO), tetramethylcyclotetrasiloxane (TMCTS), tetramethyl-diethoxyl-disiloxane (TMDDSO), dimethyl-dimethoxyl-silane (DMDMS) or combinations thereof. Additional precursors for the deposition of silicon nitride include SiₓN_{y}H_{z} containing precursors, such as sillyl-amine and its derivatives including trisillylamine (TSA) and disillylamine (DSA), SiₓN_{y}H_{z}O_{zz} containing precursors, SiₓN_{y}H_{z}H_{zz} containing precursors, or combinations thereof.

Processing precursors include boron containing compounds, hydrogen containing compounds, oxygen containing compounds, nitrogen containing compounds, or combinations thereof. Suitable examples of the boron containing compounds include BH₃, B₂H₆, BF₃, BCl₃, and the like. Examples of suitable processing precursors include one or more of compounds selected from the group consisting of H₂, a H₂/N₂ mixture, NH₃, NH₄OH, O₃, O₂, H₂O₂, N₂, NₓH_{y} compounds including N₂H₄ vapor, NO, N₂O, NO₂, water vapor, or combinations thereof. The processing precursors may be plasma exited, such as in the RPS unit, to include N* and/or H* and/or O* containing radicals or plasma, for example, NH₃, NH₂*, NH*, N*, H*, O*, N*O*, or combinations thereof. The process precursors may alternatively, include one or more of the precursors described herein.

The processing precursors may be plasma excited in the first plasma region 115 to produce process gas plasma and radicals including B*, N* and/or H* and/or O* containing radicals or plasma, or combinations thereof. Alternatively, the processing precursors may already be in a plasma state after passing through a remote plasma system prior to introduction to the first plasma region 115.

The excited processing precursor is then delivered to the second plasma region 133 for reaction with the precursors though apertures 114. Once in the processing volume, the processing precursor may mix and react to deposit the dielectric materials on the substrate.

In one embodiment, the flowable CVD process performed in the deposition chamber 100 may deposit the doped silicon containing gas, such as boron (B) doped silicon layer (Si-B) or other suitable boron-silicon containing material as needed.

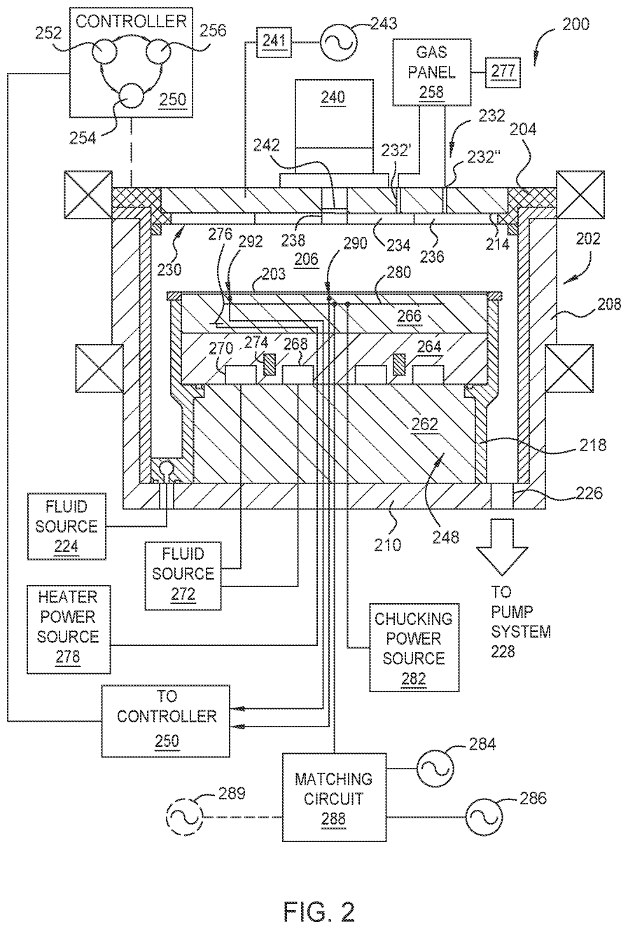

FIG. 2 is a sectional view of one example of a processing chamber 200 suitable for performing a patterning process to etch a spacer layer, such as a doped silicon containing material, along with a hardmask layer on a substrate using an etching process, such as both anisotropic etching and isotropic etching. Suitable processing chambers that may be adapted for use with the teachings disclosed herein include, for example, a CENTRIS® SYM3™ processing chamber available from Applied Materials, Inc. of Santa Clara, California. Although the processing chamber 200 is shown including a plurality of features that enable superior etching performance, it is contemplated that other processing chambers may be adapted to benefit from one or more of the inventive features disclosed herein.

The processing chamber 200 includes a chamber body 202 and a lid 204 which enclose an interior volume 206. The chamber body 202 is typically fabricated from aluminum, stainless steel or other suitable material. The chamber body 202 generally includes sidewalls 208 and a bottom 210. A substrate support pedestal access port (not shown) is generally defined in a sidewall 208 and selectively sealed by a slit valve to facilitate entry and egress of a substrate 203 from the processing chamber 200. An exhaust port 226 is defined in the chamber body 202 and couples the interior volume 206 to a vacuum pump system 228. The vacuum pump system 228 generally includes one or more pumps and throttle valves utilized to evacuate and regulate the pressure of the interior volume 206 of the processing chamber 200. In one implementation, the vacuum pump system 228 maintains the pressure inside the interior volume 206 at operating pressures typically between about 10 mTorr to about 500 Torr.

The lid 204 is sealingly supported on the sidewall 208 of the chamber body 202. The lid 204 may be opened to allow access to the interior volume 206 of the processing chamber 200. The lid 204 includes a window 242 that facilitates optical process monitoring. In one implementation, the window 242 is comprised of quartz or other suitable material that is transmissive to a signal utilized by an optical monitoring system 240 mounted outside the processing chamber 200.

The optical monitoring system 240 is positioned to view at least one of the interior volume 206 of the chamber body 202 and/or the substrate 203 positioned on a substrate support pedestal assembly 248 through the window 242. In one embodiment, the optical monitoring system 240 is coupled to the lid 204 and facilitates an integrated deposition process that uses optical metrology to provide information that enables process adjustment to compensate for incoming substrate pattern feature inconsistencies (such as thickness, and the like), and provide process state monitoring (such as plasma monitoring, temperature monitoring, and the like) as needed. One optical monitoring system that may be adapted to benefit from the disclosure is the EyeD® full-spectrum, interferometric metrology module, available from Applied Materials, Inc., of Santa Clara, Calif.

A gas panel 258 is coupled to the processing chamber 200 to provide process and/or cleaning gases to the interior volume 206. In the example depicted in FIG. 2, inlet ports 232′, 232″ (collectively referred to as 232) are provided in the lid 204 to allow gases to be delivered from the gas panel 258 to the interior volume 206 of the processing chamber 200. In one implementation, the gas panel 258 is adapted to provide fluorinated process gas through the inlet ports 232′, 232″ and into the interior volume 206 of the processing chamber 200. In one implementation, the process gas provided from the gas panel 258 includes at least a fluorinated gas, chlorine, and a carbon containing gas, an oxygen gas, a nitrogen containing gas and a chlorine containing gas. Examples of fluorinated and carbon containing gases include CHF₃, CH₂F₂, and CF₄. Other fluorinated gases may include one or more of C₂F, C₄F₆, C₃F₆, and C₅F₈. Examples of the oxygen containing gas include O₂, CO₂, CO, N₂O, NO₂, O₃, H₂O, and the like. Examples of the nitrogen containing gas include N₂, NH₃, N₂O, NO₂, and the like. Examples of the chlorine containing gas include HCl, Cl₂, CCl₄, CHCl₃, CH₂Cl₂, CH₃Cl, and the like. Suitable examples of the carbon containing gas include methane (CH₄), ethane (C₂H₆), ethylene (C₂H₄), and the like.

A showerhead assembly 230 is coupled to an interior surface 214 of the lid 204. The showerhead assembly 230 includes a plurality of apertures that allow the gases to flow through the showerhead assembly 230 from the inlet ports 232′, 232″ into the interior volume 206 of the processing chamber 200 in a predefined distribution across the surface of the substrate 203 being processed in the processing chamber 200.

A remote plasma source 277 may be optionally coupled to the gas panel 258 to facilitate dissociating a gas mixture from a remote plasma prior to entering into the interior volume 206 for processing. An RF power source 243 is coupled through a matching network 241 to the showerhead assembly 230. The RF power source 243 typically is capable of producing up to about 3000 W at a tunable frequency in a range from about 50 kHz to about 200 MHz.

The showerhead assembly 230 additionally includes a region transmissive to an optical metrology signal. The optically transmissive region or passage 238 is suitable for allowing the optical monitoring system 240 to view the interior volume 206 and/or the substrate 203 positioned on the substrate support pedestal assembly 248. The passage 238 may be a material, an aperture or plurality of apertures formed or disposed in the showerhead assembly 230 that is substantially transmissive to the wavelengths of energy generated by, and reflected back to, the optical monitoring system 240.

In one implementation, the showerhead assembly 230 is configured with a plurality of zones that allow for separate control of gas flowing into the interior volume 206 of the processing chamber 200. In the example illustrated in FIG. 2, the showerhead assembly 230 has an inner zone 234 and an outer zone 236 that are separately coupled to the gas panel 258 through separate inlet ports 232′, 232″.

The substrate support pedestal assembly 248 is disposed in the interior volume 206 of the processing chamber 200 below the gas distribution (showerhead) assembly 230. The substrate support pedestal assembly 248 holds the substrate 203 during processing. The substrate support pedestal assembly 248 generally includes a plurality of lift pins (not shown) disposed therethrough that are configured to lift the substrate 203 from the substrate support pedestal assembly 248 and facilitate exchange of the substrate 203 with a robot (not shown) in a conventional manner. An inner liner 218 may closely circumscribe the periphery of the substrate support pedestal assembly 248.

In one implementation, the substrate support pedestal assembly 248 includes a mounting plate 262, a base 264 and an electrostatic chuck 266. The mounting plate 262 is coupled to the bottom 210 of the chamber body 202 and includes passages for routing utilities, such as fluids, power lines and sensor leads, among others, to the base 264 and the electrostatic chuck 266. The electrostatic chuck 266 includes at least one clamping electrode 280 for retaining the substrate 203 below showerhead assembly 230. The electrostatic chuck 266 is driven by a chucking power source 282 to develop an electrostatic force that holds the substrate 203 to the chuck surface, as is conventionally known. Alternatively, the substrate 203 may be retained to the substrate support pedestal assembly 248 by clamping, vacuum or gravity.

At least one of the base 264 or electrostatic chuck 266 may include at least one optional embedded heater 276, at least one optional embedded isolator 274, and a plurality of conduits 268, 270 to control the lateral temperature profile of the substrate support pedestal assembly 248. The conduits 268, 270 are fluidly coupled to a fluid source 272 that circulates a temperature regulating fluid therethrough. The heater 276 is regulated by a power source 278. The conduits 268, 270 and heater 276 are utilized to control the temperature of the base 264, thereby heating and/or cooling the electrostatic chuck 266 and ultimately, the temperature profile of the substrate 203 disposed thereon. The temperature of the electrostatic chuck 266 and the base 264 may be monitored using a plurality of temperature sensors 290, 292. The electrostatic chuck 266 may further have a plurality of gas passages (not shown), such as grooves, that are formed in a substrate support pedestal supporting surface of the electrostatic chuck 266 and fluidly coupled to a source of a heat transfer (or backside) gas, such as He. In operation, the backside gas is provided at controlled pressure into the gas passages to enhance the heat transfer between the electrostatic chuck 266 and the substrate 203.

In one implementation, the substrate support pedestal assembly 248 is configured as a cathode and includes the electrode 280 that is coupled to a plurality of RF bias power sources 284, 286. The RF bias power sources 284, 286 are coupled between the electrode 280 disposed in the substrate support pedestal assembly 248 and another electrode, such as the showerhead assembly 230 or ceiling (lid 204) of the chamber body 202. The RF bias power excites and sustains a plasma discharge formed from the gases disposed in the processing region of the chamber body 202.

In the example depicted in FIG. 2, the dual RF bias power sources 284, 286 are coupled to the electrode 280 disposed in the substrate support pedestal assembly 248 through a matching circuit 288. The signal generated by the RF bias power sources 284, 286 is delivered through the matching circuit 288 to the substrate support pedestal assembly 248 through a single feed to ionize the gas mixture provided in the plasma processing chamber 200, thereby providing ion energy necessary for performing a deposition or other plasma enhanced process. The RF bias power sources 284, 286 are generally capable of producing an RF signal having a frequency of from about 50 kHz to about 200 MHz and a power between about 0 Watts and about 5000 Watts. An additional bias power source 289 may be coupled to the electrode 280 to control the characteristics of the plasma.

In one mode of operation, the substrate 203 is disposed on the substrate support pedestal assembly 248 in the plasma processing chamber 200. A process gas and/or gas mixture is introduced into the chamber body 202 through the showerhead assembly 230 from the gas panel 258. The vacuum pump system 228 maintains the pressure inside the chamber body 202 while removing deposition by-products.

A controller 250 is coupled to the processing chamber 200 to control operation of the processing chamber 200. The controller 250 includes a central processing unit (CPU) 252, a memory 254, and a support circuit 256 utilized to control the process sequence and regulate the gas flows from the gas panel 258. The CPU 252 may be any form of general purpose computer processor that may be used in an industrial setting. The software routines can be stored in the memory 254, such as random access memory, read only memory, floppy, or hard disk drive, or other form of digital storage. The support circuit 256 is conventionally coupled to the CPU 252 and may include cache, clock circuits, input/output systems, power supplies, and the like. Bi-directional communications between the controller 250 and the various components of the processing chamber 200 are handled through numerous signal cables.

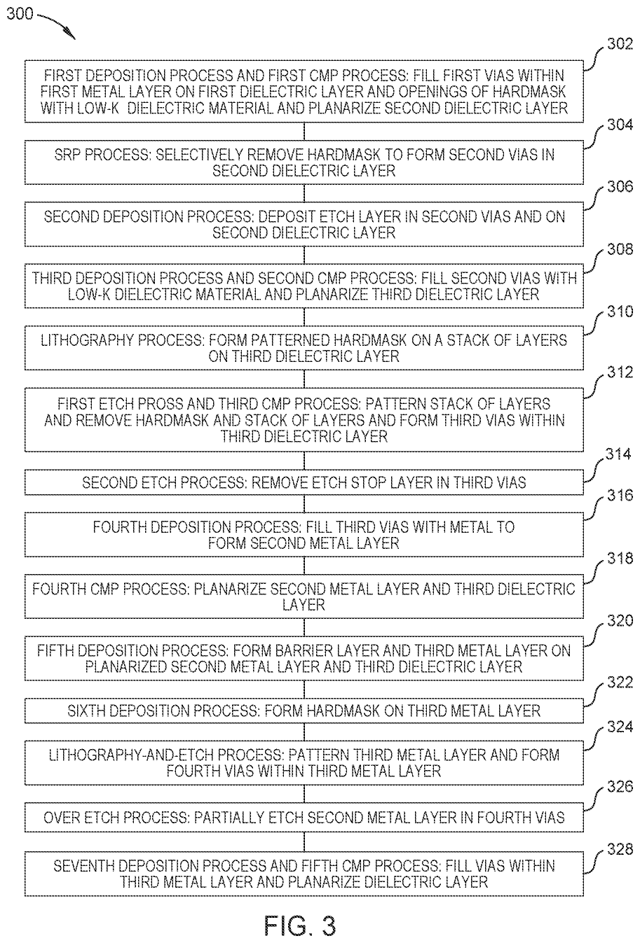

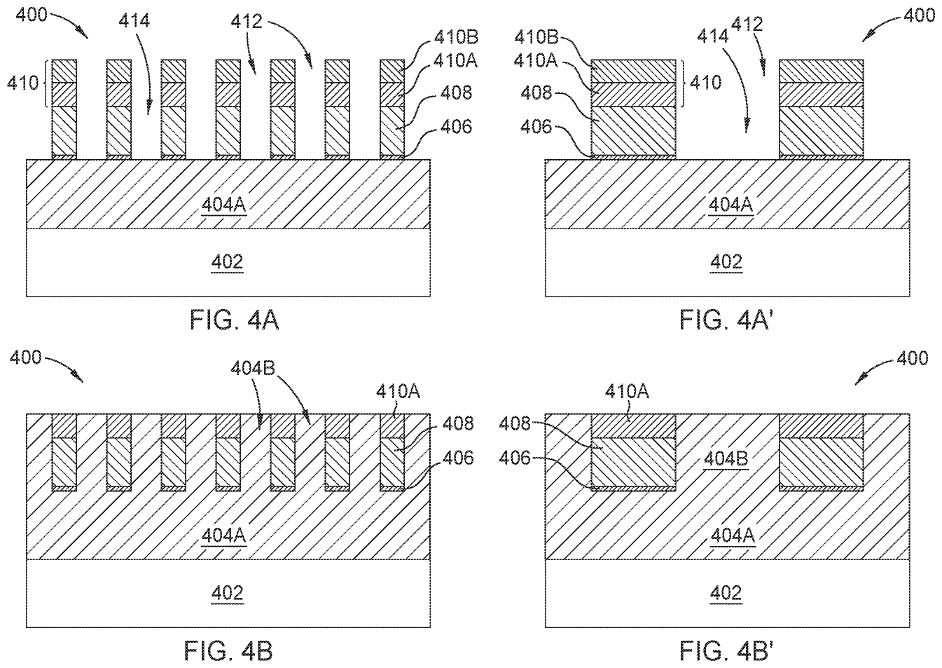

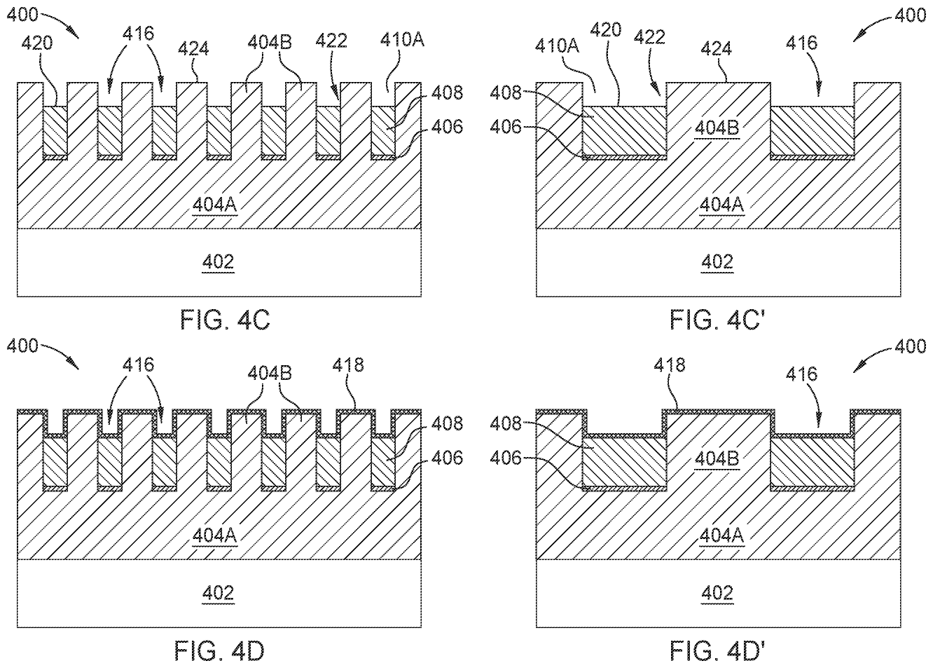

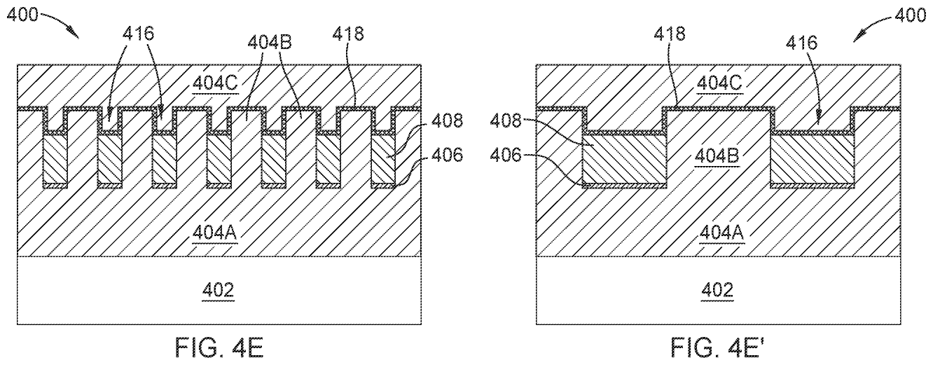

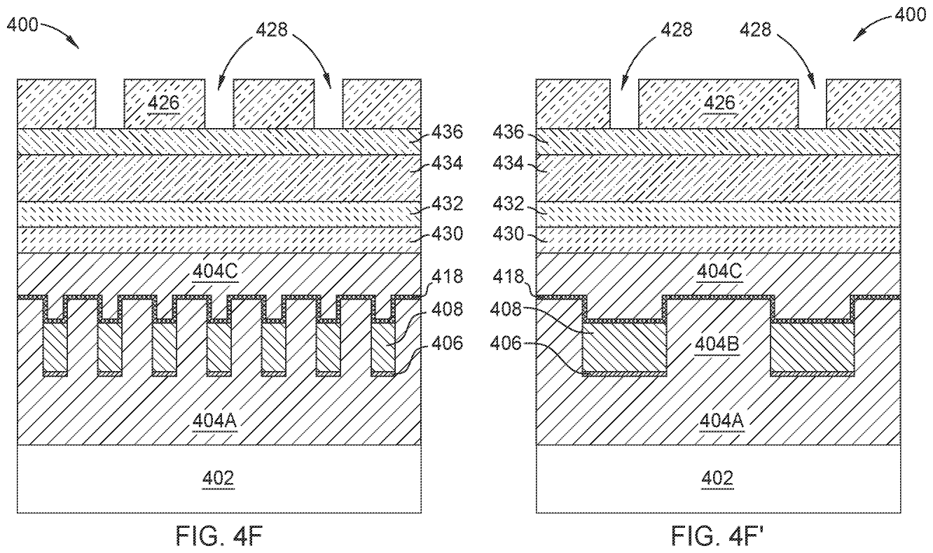

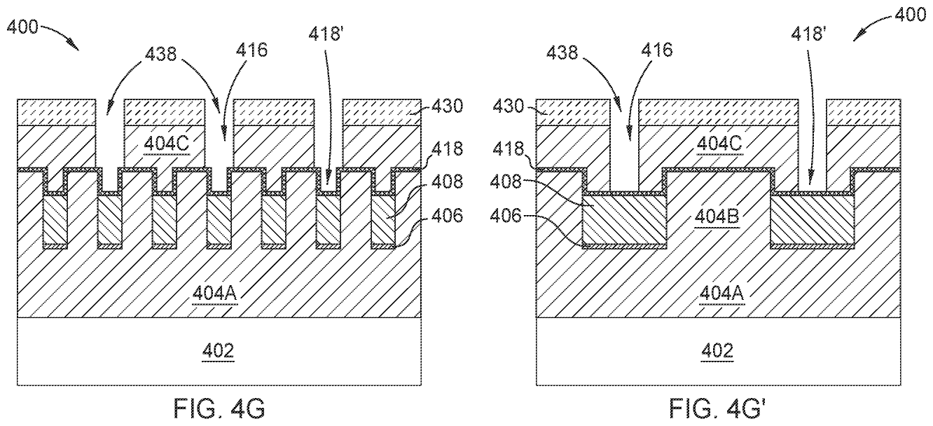

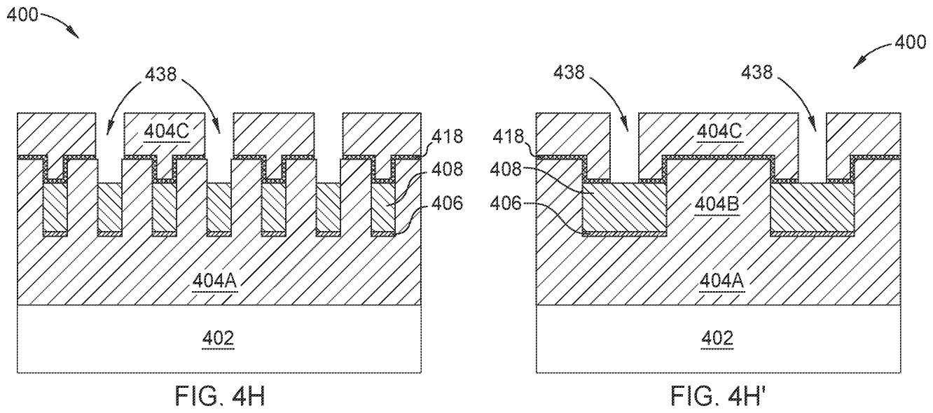

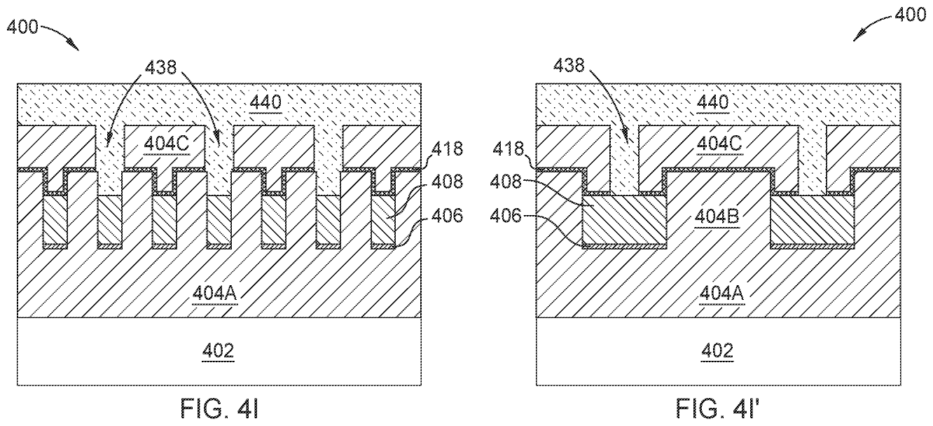

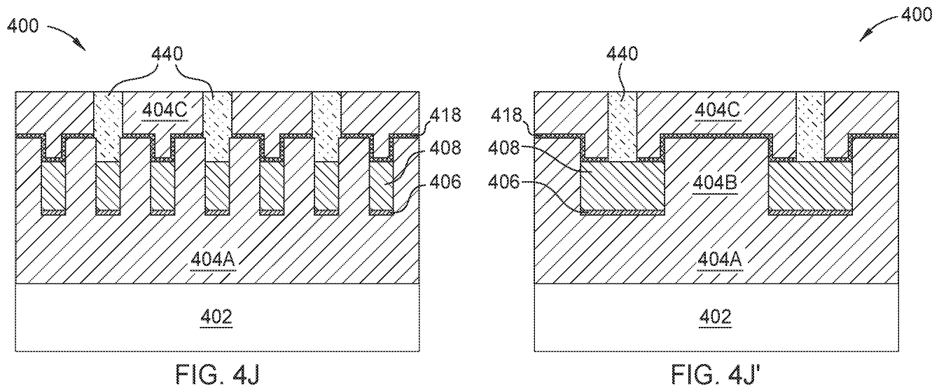

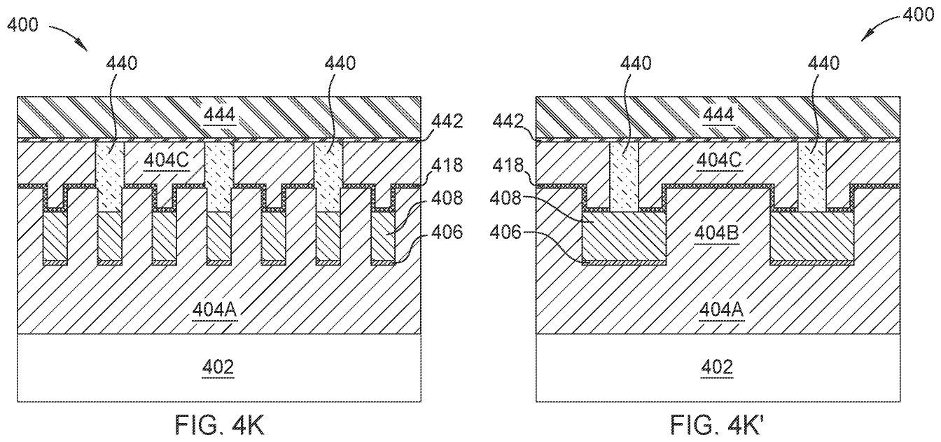

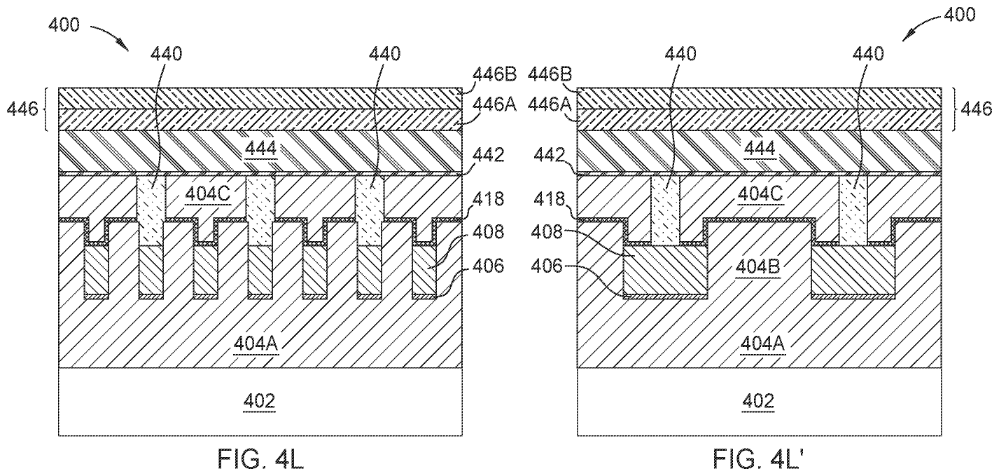

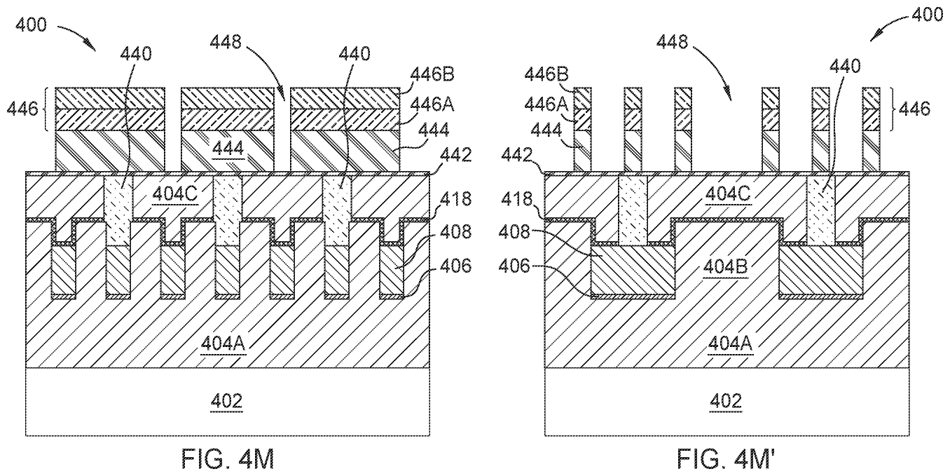

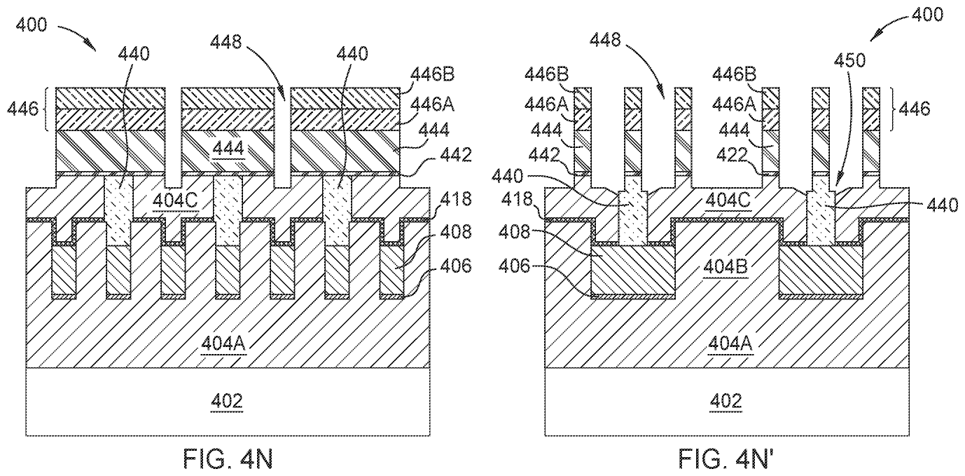

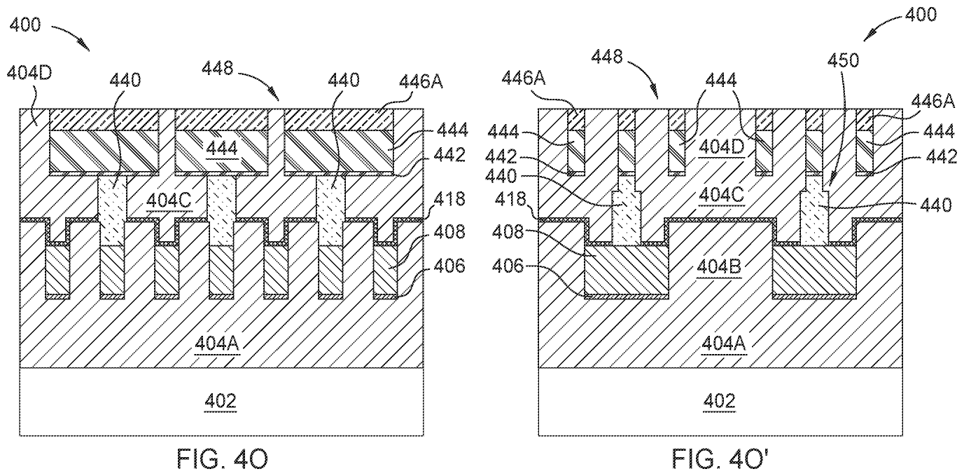

FIG. 3 is a flow diagram of a method 300 for fabricating fully self-aligned vias in a nanostructure 400 according to one embodiment. FIGS. 4A, 4A′, 4B, 4B′, 4C, 4C′, 4D, 4D′, 4E, 4E′, 4F, 4F′, 4G, 4G′, 4H, 4H′, 4I, 4I′, 4J, and 4J′ are cross-sectional views of a portion of the nanostructure 400 corresponding to various stages of the method 300. The method 300 may be utilized to form features in a material layer, such as interconnects for backend-of-line (BEOL) layers. Alternatively, the method 300 may be beneficially utilized to etch any other types of structures as needed.

As shown in FIGS. 4A and 4A′; the nanostructure 400 includes a substrate 402, a first dielectric layer 404A disposed on the substrate 402, a barrier layer 406 disposed on the first dielectric layer 404A, a first metal layer 408 disposed on the barrier layer 406, and a hardmask 410 disposed on the first metal layer 408.

The substrate 402 may include a material such as crystalline silicon (e.g., Si<100>or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire. The substrate 402 may have various dimensions, such as 200 mm, 300 mm, 450 mm or other diameter wafers, as well as, rectangular or square panels.

The first dielectric layer 404A may be formed of flowable low-k dielectric material including silicon containing dielectric material, such silicon oxide, silicon carbide, silicon nitride, silicon oxynitride, or silicon oxycarbide. The first dielectric layer 404A may be formed by delivering flowable dielectric material in a liquid phase onto the substrate 402 by an appropriate deposition process, such as a process that deposits flowable dielectric material using a flowing mechanism, and then hardening the precursor into a solid phase by steam annealing, hot pressing, and sintering at high temperatures. Example deposition processes that use a flowing mechanism include flowable CVD and spin-on coating. Other deposition processes may be used.

The barrier layer 406 may be formed of material that provides etch selectivity from the first metal layer 408, such as titanium nitride (TiN), titanium (Ti), tantalum nitride (TaN), tantalum (Ta), aluminum oxide (Al₂O₃), titanium oxide (TiO₂), tungsten carbide (WC), tungsten boron carbide (WBC), silicon boride (SiBx), silicon carbonitride (SiCN), boron carbide (BC), amorphous carbon, boron nitride (BN), boron carbon nitride (BCN), carbon doped oxides, porous silicon dioxide, silicon nitride (SiN), oxycarbonitrides, polymers, phosphosilicate glass, fluorosilicate (SiOF) glass, organosilicate glass (SiOCH), other suitable oxide material, other suitable carbide material, other suitable oxycarbide material, or other suitable oxynitride, such that the barrier layer 406 can function as an etch stop for a subsequent etch process. In one particular example, the barrier layer 406 is formed of titanium nitride (TiN). The barrier layer 406 may be deposited on the first dielectric layer 404A using any appropriate deposition process, such as chemical vapor deposition (CVD), spin-on, physical vapor deposition (PVD), or the like.

The first metal layer 408 formed of first metal may include ruthenium (Ru) or any metal that can be etched, such as nickel (Ni), cobalt (Co), molybdenum (Mo), tungsten (W), titanium (Ti), and iron (Fe). The first metal layer 408 may be deposited on the first dielectric layer 404A using any appropriate deposition process, such as chemical vapor deposition (CVD), spin-on, physical vapor deposition (PVD), or the like.

The hardmask 410 may include two or more hardmask layers formed of tetra-ethyl-orthosilicate (TEOS), silicon nitride (Si₃N₄), silicon oxynitride (SiON), silicon oxide, silicon boride (SiBx), silicon carbonitride (SiCN), boron carbide (BC), amorphous carbon, boron nitride (BN), boron carbon nitride (BCN), carbon doped oxides, porous silicon dioxide, oxycarbonitrides, polymers, phosphosilicate glass, fluorosilicate (SiOF) glass, organosilicate glass (SiOCH), other suitable oxide material, other suitable carbide material, other suitable oxycarbide material, or other suitable oxynitride material. In one particular example, the hardmask 410 includes a lower hardmask 410A formed of silicon nitride (Si₃N₄) in direct contact with the first metal layer 408 and an upper hardmask 410B, formed of TEOS, stacked on the lower hardmask 410A. In some embodiments, the hardmask 410 is formed of amorphous silicon (a-Si). The hardmask 410 may be formed using any appropriate deposition process, such as atomic layer deposition (ALD), chemical vapor deposition (CVD), spin-on, physical vapor deposition (PVD), or the like, and patterned with openings 412 using any appropriate lithography process. The barrier layer 406 and the first metal layer 408 are patterned with first vias 414 using the hardmask 410.

The method 300 begins with block 302, in which a first deposition process and a first chemical mechanical polishing (CMP) process are performed, as shown in FIGS. 4B and 4B′. The first deposition process fills the openings 412 of the hardmask 410 and the first vias 414 within the barrier layer 406 and the first metal layer 408 underneath the hardmask 410 and on the first dielectric layer 404A with the flowable low-k dielectric material and forms a second dielectric layer 4046 in the first vias 414. The second dielectric layer 4046 is formed by delivering flowable dielectric material in a liquid phase onto the substrate 402 by an appropriate deposition process. The first CMP process planarizes the second dielectric layer 404B. The first CMP process stops at the lower hardmask 410A and thus removes only the upper hardmask 410B. The first deposition process may be performed in a processing chamber, such as the processing chamber 100 shown in FIG. 1.

In block 304, a selective removal plasma (SRP) process is performed to selectively remove the lower hardmask 410A, forming second vias 416 within the second dielectric layer 4046, as shown in FIGS. 4C and 4C′. As shown, the second vias 416 are self- aligned with the underlying patterned first metal layer (also referred to as a “first interconnect structure”) 408. The SRP process may be performed by a dry etch process using an etch gas that etches the lower hardmask 410A at a higher etch rate than the second dielectric layer 404B. The SRP process may be performed in a processing chamber, such as the processing chamber 200 shown in FIG. 2.

In block 306, a second deposition process is performed to deposit an etch stop layer 418 in the second vias 416 and on the second dielectric layer 4046 (i.e., top surfaces 420 of the first metal layer 408 in the second vias 416, sidewalls 422 of the second vias 416, and top surfaces 424 of the second dielectric layer 404B, shown in FIGS. 4C and 4C′), as shown in FIGS. 4D and 4D′. The etch stop layer 418 may be formed of two or more layers including an aluminum oxynitride (ALON) layer and a silicon carbon nitride (SiCN) layer, and have a combined thickness of about 2 nm. The etch stop layer 418 may be formed using any appropriate deposition process, such as atomic layer deposition (ALD), chemical vapor deposition (CVD), spin-on, physical vapor deposition (PVD), or the like.

In block 308, a third deposition process and a second CMP process are performed, as shown in FIGS. 4E and 4E′. The third deposition process fills the second vias 416 with the flowable low-k dielectric material over the etch stop layer 418 and forms a third dielectric layer 404C in the second vias 416 and over the second dielectric layer 404B. The third deposition process may be the same as the first deposition process in block 302. The second CMP process planarizes the third dielectric layer 404C.

In block 310, a lithography process is performed to form a patterned hardmask 426 with openings 428 on a stack of layers, a barrier layer 430 formed on the third dielectric layer 404C, a first layer 432 formed on the barrier layer 430, a second layer 434 formed on the first layer 432, and a third layer 436 formed on the second layer 434, as shown in FIGS. 4F and 4F′.

The hardmask 426 may be formed of tetra-ethyl-orthosilicate (TEOS), silicon nitride (Si₃N₄), silicon oxynitride (SiON), silicon oxide, silicon boride (SiBx), silicon carbonitride (SiCN), boron carbide (BC), amorphous carbon, boron nitride (BN), boron carbon nitride (BCN), carbon doped oxides, porous silicon dioxide, oxycarbonitrides, polymers, phosphosilicate glass, fluorosilicate (SiOF) glass, organosilicate glass (SiOCH), other suitable oxide material, other suitable carbide material, other suitable oxycarbide material, or other suitable oxynitride material. In one particular example, the hardmask 426 is formed of TEOS. The hardmask 426 may be formed using any appropriate deposition process, such as atomic layer deposition (ALD), chemical vapor deposition (CVD), spin-on, physical vapor deposition (PVD), or the like, and patterned with openings 428 using any appropriate lithography process.

The barrier layer 430 may be formed of material that provides etch selectivity from the third dielectric layer 404C, such as titanium nitride (TiN), titanium (Ti), tantalum nitride (TaN), tantalum (Ta), aluminum oxide (Al₂O₃), titanium oxide (TiO₂), tungsten carbide (WC), tungsten boron carbide (WBC), silicon boride (SiBₓ), silicon carbonitride (SiCN), boron carbide (BC), amorphous carbon, boron nitride (BN), boron carbon nitride (BCN), carbon doped oxides, porous silicon dioxide, silicon nitride (SiN), oxycarbonitrides, polymers, phosphosilicate glass, fluorosilicate (SiOF) glass, organosilicate glass (SiOCH), other suitable oxide material, other suitable carbide material, other suitable oxycarbide material, or other suitable oxynitride, such that the barrier layer 430 can function as an etch stop for a subsequent etch process. In one particular example, the barrier layer 430 is formed of titanium nitride (TiN). The barrier layer 430 may be deposited on the third dielectric layer 404C using any appropriate deposition process, such as chemical vapor deposition (CVD), spin-on, physical vapor deposition (PVD), or the like.

The second layer 434 may be formed using any appropriate deposition process, such as chemical vapor deposition (CVD), spin-on, physical vapor deposition (PVD), or the like.

The third layer 436 may be formed using any appropriate deposition process, such as chemical vapor deposition (CVD), spin-on, physical vapor deposition (PVD), or the like.

In block 312, a first etch process and a third CMP process are performed, as shown in FIGS. 4G and 4G′. The first etch process using the hardmask 426 patterns the stack of layers (i.e., the barrier layer 430, the first layer 432, the second layer 434, and the third layer 436) and the third dielectric layer 404C with third vias 438. As shown, the third vias 438 are self-aligned with the second vias 416 in which the second metal layer (also referred to as a “second interconnect structure”) 408 is formed. The first etch process stops at the etch stop layer 418. The third CMP process planarizes top surfaces of the nanostructure 400. The third CMP process stops at the barrier layer 430 and thus removes the patterned hardmask 426, the first layer 432, the second layer 434, and the third layer 436.

In block 314, a second etch process is performed as shown in FIGS. 4H and4H′ to remove the remaining barrier layer 430 and portions 418′ of the etch stop layer 418 within the third vias 438 (shown in FIGS. 4G and 4G′).

In block 316, a fourth deposition process is performed to fill the third vias 438 with second metal to form a second metal layer 440 within the third vias 438 and over the third dielectric layer 404C, as shown in FIGS. 41 and 41′. The second metal layer 440 formed of second metal may include tungsten (W), or any metal that can be etched, such as nickel (Ni), cobalt (Co), ruthenium (Ru), molybdenum (Mo), titanium (Ti), and iron (Fe). In some embodiments, the second metal layer 440 is formed of different metal from the first metal layer 408 (referred to as a “hybrid metal” configuration). In one particular example, the second metal layer 440 is formed of tungsten (W) and the first metal layer 408 is formed of ruthenium (Ru). In another example, the first metal layer 408 and the second metal layer 440 is each formed of ruthenium (Ru). The second metal layer 440 may be formed using any appropriate deposition process, such as chemical vapor deposition (CVD), spin-on, physical vapor deposition (PVD), or the like.

In block 318, a fourth CMP process is performed to planarize the second metal layer 440 and the third dielectric layer 404C and remove portions of the second metal layer 440 outside of the third vias 438, as shown in FIGS. 4J and 4J′.

In block 320, a fifth deposition process is performed to form a barrier layer 442 on the planarized the second metal layer 440 and the third dielectric layer 404C, and a third metal layer 444 on the barrier layer 442, as shown in FIGS. 4K and 4K′. The barrier layer 442 may be formed of the same material as the barrier layer 406. In one particular example, the barrier layer 442 is formed of titanium nitride (TiN). The third metal layer 444 formed of third metal may include the same first metal as the first metal layer 408. In one particular example, the third metal layer 444 is formed of ruthenium (Ru). In an example hybrid metal configuration, the first metal layer 408 and the third metal layer 444 are formed ruthenium (Ru), and the second metal layer 440 within the third vias 438 is formed of tungsten (W). In another example, the first metal layer 408, the second metal layer 440, and the third metal layer 444 are each formed of ruthenium (Ru). The barrier layer 442 and the third metal layer 444 may be formed using any appropriate deposition process, such as chemical vapor deposition (CVD), spin-on, physical vapor deposition (PVD), or the like.

In block 322, a sixth deposition process is performed to form a hardmask 446 on the third metal layer 444, as shown as FIGS. 4L and 4L′. The hardmask 446 may be formed of the same material as the hardmask 410. In one particular example, the hardmask 446 includes a lower hardmask 446A formed of silicon nitride (Si₃N₄) in direct contact with the third metal layer 444 and an upper hardmask 446B, formed of TEOS, stacked on the lower hardmask 446A. In some embodiments, the hardmask 446 is formed of amorphous silicon (a-Si). The hardmask 446 may be formed using any appropriate deposition process, such as atomic layer deposition (ALD), chemical vapor deposition (CVD), spin-on, physical vapor deposition (PVD), or the like.

In block 324, a lithography-and-etch process is performed to pattern the third metal layer 444 and form fourth vias 448 within the third metal layer 444, as shown in FIGS. 4M and 4M′. As shown, the patterned third metal layer 444 are self-aligned with the third vias in which the third metal layer (also referred to as a “third interconnect structure”) 440 is formed. In block 324, the hardmask 446 is patterned using any appropriate lithography process. The third metal layer 444 is patterned by an etch process using the hardmask 446.

In block 326, an over etch process is performed to partially etch the second metal layer 440 in the fourth vias 448, forming a step height difference 450, as shown in FIGS. 4N and 4N′. The over etch process in block 326 may be performed using any appropriate etch process. This process reduces potential shorting of the second metal layer 440 (i.e., interconnect structure) to an adjacent third metal layer 444 (i.e., interconnect structure).

In block 328, a seventh deposition process and a fifth CMP process are performed, as shown in FIGS. 40 and 40′. The seventh deposition process fills the fourth vias 448 with the flowable low-k dielectric materials and forms a fourth dielectric layer 404D in the fourth vias 448 and over the hardmask 446. The seventh deposition process may be the same as the first deposition process in block 302. The fifth CMP process planarizes the fourth dielectric layer 404D. The fifth CMP process stops at the lower hardmask 446A, and thus removes only the upper hardmask 446B.

The embodiments described herein provide methods for forming a fully self-aligned vias. Vias, which are filled with tungsten (W) or ruthenium (Ru) to form interconnect structures, in multiple metal layers are fully self-aligned, and thus device failure due to misalignment of interconnect structures is greatly reduced.

While the foregoing is directed to embodiments of the present disclosure, other and further embodiments of the disclosure may be devised without departing from the basic scope thereof, and the scope thereof is determined by the claims that follow.

1. A method of fabricating fully self-aligned vias, the method comprising:
performing a first deposition process to fill openings of a first hardmask and first vias formed within a first metal layer formed of first metal underneath the first hardmask and on a first dielectric layer formed of low-k dielectric material, with the low-k dielectric material, forming a second dielectric layer;
performing a first chemical mechanical polishing (CMP) process to planarize the second dielectric layer and partially remove the first hardmask;
performing a selective removal plasma process to selectively remove the remaining first hardmask and form second vias within the second dielectric layer;
performing a second deposition process to deposit an etch stop layer in the second vias and on the second dielectric layer;
performing a third deposition process to fill the second vias over the etch stop layer with the low-k dielectric material, forming a third dielectric layer;
performing a second CMP process to planarize the third dielectric layer;
performing a first lithography-and-etch process to form third vias in the third dielectric layer, the first lithography-and-etch process comprising a lithography process, an etch process, and a third CMP process;
performing a fourth deposition process to fill the third vias with second metal to form a second metal layer in the third vias and on the third dielectric layer;
performing a fourth CMP process to planarize the second metal layer and the third dielectric layer and remove portions of the second metal layer outside the third vias;
performing a fifth deposition process to form a third metal layer of third metal on the second metal layer and the third dielectric layer;
performing a sixth deposition process to form a second hardmask on the third metal layer;
performing a second lithography-and-etch process to form fourth vias in the third metal layer;
performing an over etch process to partially etch the second metal layer in the fourth vias;
performing a seventh deposition process to fill the fourth vias with the low-k dielectric material, forming a fourth dielectric layer; and
performing a fifth CMP process to planarize the fourth dielectric layer and partially remove the second hardmask.

2. The method of claim 1, wherein
first metal layer comprises ruthenium (Ru),
second metal layer comprises tungsten (W), and
third metal layer comprises ruthenium (Ru).

3. The method of claim 1, wherein
first metal layer comprises ruthenium (Ru),
second metal layer comprises ruthenium (Ru), and
third metal layer comprises ruthenium (Ru).

4. The method of claim 1, wherein
the low-k dielectric material comprises silicon containing flowable dielectric material.

5. The method of claim 1, wherein
the first hardmask comprises a lower hardmask deposited on the first metal layer, and an upper hardmask deposited on the lower hardmask,
the lower hardmask comprises silicon nitride (Si₃N₄), and
the upper hardmask comprises tetra-ethyl-orthosilicate (TEOS).

6. The method of claim 5, wherein
the first CMP process removes the upper hardmask, and
the selective removal plasma process removes the lower hardmask.

7. The method of claim 1, wherein
the second hardmask comprises a lower hardmask deposited on the first metal layer, and an upper hardmask deposited on the lower hardmask,
the lower hardmask comprises silicon nitride (Si₃N_{4l ), and}
the upper hardmask comprises tetra-ethyl-orthosilicate (TEOS).

8. The method of claim 1, wherein
the first hardmask and the second hardmask each comprise amorphous silicon (a-Si).

9. The method of claim 1, wherein
the etch stop layer comprises a layer comprising aluminum oxynitride (ALON) and a layer comprising silicon carbon nitride (SiCN).

10. A nanostructure formed on a substrate, comprising:
a first dielectric layer formed on a substrate;
a second dielectric layer disposed on the first dielectric layer, the second dielectric layer having a plurality of first interconnect structures formed therein;
a third dielectric layer disposed on the second dielectric layer, the third dielectric layer having a plurality of second interconnect structures formed therein, wherein the plurality of second interconnect structures are self-aligned with the plurality of first interconnect structures; and
a fourth dielectric layer disposed on the third dielectric layer, the fourth dielectric layer having a plurality of third interconnect structures formed therein, wherein the plurality of third interconnect structures are self-aligned with the plurality of second interconnect structures.

11. The nanostructure of claim 10, wherein :
the plurality of first interconnect structures comprise ruthenium (Ru),
the plurality of second interconnect structures comprise tungsten (W), and
the plurality of third interconnect structures comprise ruthenium (Ru).

12. The nanostructure of claim 10, wherein :
the plurality of first interconnect structures comprise ruthenium (Ru),
the plurality of second interconnect structures comprise ruthenium (Ru), and
the plurality of third interconnect structures comprise ruthenium (Ru).

13. The nanostructure of claim 10, wherein :
the first, second, third, and fourth dielectric layers each comprise silicon containing flowable dielectric material.

14. The nanostructure of claim 10, further comprising:
a first barrier layer between the first dielectric layer and the plurality of first interconnect structures; and
a second barrier layer between the plurality of second interconnect structures and the plurality of third interconnect structures.

15. A method of fabricating fully self-aligned vias, the method comprising:
performing a first deposition process to fill openings of a first hardmask and first vias formed within a first metal layer formed of first metal underneath the first hardmask and on a first dielectric layer formed of low-k dielectric material, with the low-k dielectric material, forming a second dielectric layer;
performing a first chemical mechanical polishing (CMP) process to planarize the second dielectric layer and partially remove the first hardmask;
performing a selective removal plasma process to selectively remove the remaining first hardmask and form second vias within the second dielectric layer;
performing a second deposition process to deposit an etch stop layer in the second vias and on the second dielectric layer;
performing a third deposition process to fill the second vias over the etch stop layer with the low-k dielectric material, forming a third dielectric layer;
performing a second CMP process to planarize the third dielectric layer,

16. The method of claim 15, wherein
the low-k dielectric material comprises silicon containing flowable dielectric material,
the first hardmask comprises a lower hardmask deposited on the first metal layer, and an upper hardmask deposited on the lower hardmask,
the lower hardmask comprises silicon nitride (Si₃N₄),
the upper hardmask comprises tetra-ethyl-orthosilicate (TEOS),
the first CMP process removes the upper hardmask, and
the selective removal plasma process removes the lower hardmask.

17. The method of claim 15, further comprising:
performing a first lithography-and-etch process to form third vias in the third dielectric layer, the first lithography-and-etch process comprising a lithography process, an etch process, and a third CMP process;
performing a fourth deposition process to fill the third vias with second metal to form a second metal layer in the third vias and on the third dielectric layer;
performing a fourth CMP process to planarize the second metal layer and the third dielectric layer and remove portions of the second metal layer outside the third vias;
performing a fifth deposition process to form a third metal layer of third metal on the second metal layer and the third dielectric layer;
performing a sixth deposition process to form a second hardmask on the third metal layer;
performing a second lithography-and-etch process to form fourth vias in the third metal layer;
performing an over etch process to partially etch the second metal layer in the fourth vias;
performing a seventh deposition process to fill the fourth vias with the low-k dielectric material, forming a fourth dielectric layer; and
performing a fifth CMP process to planarize the fourth dielectric layer and partially remove the second hardmask.

18. The method of claim 17, wherein
first metal layer comprises ruthenium (Ru),
second metal layer comprises tungsten (W), and
third metal layer comprises ruthenium (Ru).

19. The method of claim 17, wherein
first metal layer comprises ruthenium (Ru),
second metal layer comprises ruthenium (Ru), and
third metal layer comprises ruthenium (Ru).

20. The method of claim 17, wherein
the second hardmask comprises a lower hardmask deposited on the first metal layer, and an upper hardmask deposited on the lower hardmask,
the lower hardmask comprises silicon nitride (Si₃N₄), and
the upper hardmask comprises tetra-ethyl-orthosilicate (TEOS).
